(19) United States
(12) Patent Application Publication
(10) Pub. No.: US 2025/0300068 A1
(43) Pub. Date: Sep. 25, 2025

(54) POWER/THERMAL VIA FOR THREE-DIMENSIONAL (3D) CHIP STACKING

(71) Applicant: QUALCOMM Incorporated, San Diego, CA (US)

(72) Inventors: Jihong CHOI, San Diego, CA (US); Giridhar NALLAPATI, San Diego, CA (US)

(21) Appl. No.: 18/614,414

(22) Filed: Mar. 22, 2024

(51) Int. Cl. H01L 23/522; H01L 21/768; H01L 23/367; H01L 23/498; H01L 23/528; H01L 25/065

(52) U.S. Cl. CPC H01L 23/5226; H01L 21/76897; H01L 23/367; H01L 23/49816; H01L 23/5283; H01L 25/0657; H01L 2225/06541

(57) ABSTRACT

A three-dimensional (3D) stacked chip is described. The 3D stacked chip includes a first die having a front-side surface and a backside surface, opposite the front-side surface. The backside surface on a front-side surface of a first redistribution layer (RDL). The 3D stacked chip also includes a second die having a front-side surface on the front-side surface of the first die and a backside surface being distal from the first RDL. The 3D stacked chip further includes a via extending from the backside surface of the second die to a back-end-of-line (BEOL) layer of the second die.

### BACKGROUND

### Field

Aspects of the present disclosure relate to integrated circuits (ICs) and, more particularly, to a power and/or thermal via for three-dimensional (3D) chip stacking.

### Background

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has increased due to the substantial number of devices that are now interconnected in a modern electronic device. The increased number of interconnect levels for supporting the increased number of devices involves more intricate processes.

State-of-the-art mobile application devices demand a small form factor, low cost, a tight power budget, and high electrical performance. Mobile package design has evolved to meet these divergent goals for enabling mobile applications that support multimedia enhancements. These mobile applications, however, are susceptible to power routing issues when multiple dies are stacked in the small form factor.

### SUMMARY

A three-dimensional (3D) stacked chip is described. The 3D stacked chip includes a first die having a front-side surface and a backside surface, opposite the front-side surface. The backside surface on a front-side surface of a first redistribution layer (RDL). The 3D stacked chip also includes a second die having a front-side surface on the front-side surface of the first die and a backside surface being distal from the first RDL. The 3D stacked chip further includes a via extending from the backside surface of the second die to a back-end-of-line (BEOL) layer of the second die.

A method for fabricating a three-dimensional (3D) stacked chip is described. The method includes bonding a front-side surface of a second die to a front-side surface of a first die. The method also includes forming a via extending from a backside surface of the second die to a back-end-of-line (BEOL) layer of the second die.

This has outlined, broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for conducting the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates an example implementation of a host system-on-a-chip (SOC), including a power/thermal via for three-dimensional (3D) chip stacking, in accordance with certain aspects of the present disclosure.

FIG. 2 shows a cross-sectional view of a stacked integrated circuit (IC) package, of the host system-on-a-chip (SOC) of FIG. 1.

FIG. 3 shows a cross-sectional view illustrating the stacked integrated circuit (IC) package of FIG. 2, incorporated into a wireless device, according to one aspect of the present disclosure.

FIG. 4 is a block diagram illustrating cross-sectional views of a 3D stacked chip having a power via, according to various aspects of the present disclosure.

FIG. 5 is a block diagram illustrating the 3D stacked chip of FIG. 4 in a package-on-package (POP) configuration, according to various aspects of the present disclosure.

FIG. 6 is a block diagram illustrating a 3D stacked system-on-a-chip (SOC) in a lidded package configuration, according to various aspects of the present disclosure.

FIGS. 7A-7G are cross-sectional diagrams illustrating a process for fabricating the 3D stacked chip of FIG. 4, having the power via, according to various aspects of the present disclosure.

FIG. 8 is a process flow diagram illustrating a method for fabricating a 3D stacked chip, according to various aspects of the present disclosure.

FIG. 9 is a block diagram showing an exemplary wireless communications system, in which an aspect of the present disclosure may be advantageously employed.

FIG. 10 is a block diagram illustrating a design workstation used for circuit, layout, and logic design of a semiconductor component such as the 3D stacked chip disclosed herein.

### DETAILED DESCRIPTION

The detailed description set forth below, in connection with the appended drawings, is intended as a description of various configurations and is not intended to represent the only configurations in which the concepts described may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form to avoid obscuring such concepts.

As described, the use of the term “and/or” is intended to represent an “inclusive OR,” and the use of the term “or” is intended to represent an “exclusive OR.” As described, the term “exemplary” used throughout this description means “serving as an example, instance, or illustration,” and should not necessarily be construed as preferred or advantageous over other exemplary configurations. As described, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described, the term “proximate” used throughout this description means “adjacent, very near, next to, or close to.” As described, the term “on” used throughout this description means “directly on” in some configurations, and “indirectly on” in other configurations.

A system hierarchy includes interconnection of active devices at a lowest system level all the way up to system level interconnections at a highest level. Electrical connections exist at each of the levels of the system hierarchy to connect different devices together on an integrated circuit (IC). As integrated circuits become more complex, however, more interconnect layers are used to provide the electrical connections between the devices. More recently, the number of interconnect levels for circuitry has increased due to the substantial number of devices that are now interconnected in a state-of-the-art mobile application device.

These interconnections include back-end-of-line (BEOL) layers, which may refer to the conductive interconnect layers for electrically coupling to front-end-of-line (FEOL) active devices of an integrated circuit (IC). The various BEOL interconnect layers are formed at corresponding BEOL interconnect levels, in which lower BEOL interconnect levels use thinner metal layers relative to upper BEOL interconnect levels. The BEOL interconnect layers may electrically couple to middle-of-line (MOL) interconnect layers, which interconnect to the FEOL active devices of an IC.

State-of-the-art mobile application devices demand a small form factor, low cost, a tight power budget, and high electrical performance. Mobile package design has evolved to meet these divergent goals for enabling mobile applications that support multimedia enhancements. Stacked die schemes and chiplet architectures are becoming mainstream as significant power performance area (PPA) yield enhancements are demonstrated for stacked die and chiplet architecture product lines. Unfortunately, successful stacked die schemes involve high power density targets, which impose significant power distribution losses.

Additionally, these mobile applications are susceptible to power routing issues when multiple dies are stacked in the small form factor. Unfortunately, power density for an IC utilized by these mobile applications is continually increasing, and the design of a power delivery network and heat dissipation is now a key bottleneck for the future advancement of IC design. Unfortunately, this problem is even more challenging when implementing a three-dimensional (3D) stacked chip architecture that is specified to extend Moore's law.

Various aspects of the present disclosure provide a power and/or thermal via for 3D chip stacking. The process flow for fabrication of the power/thermal via for 3D chip stacking may further include formation of the power/thermal vias post chip stacking. It will be understood that the term “layer” includes film and is not construed as indicating a vertical or horizontal thickness unless otherwise stated. As described, the term “substrate” may refer to a substrate of a diced wafer or may refer to a substrate of a wafer that is not diced. As further described, the term “laminate” may refer to a multilayer sheet to enable packaging of an IC device. As described, the term “chiplet” may refer to an integrated circuit block, a functional circuit block, or other like circuit block specifically designed to work with other similar chiplets to form a larger, more complex chiplet architecture. The terms “substrate,” “wafer,” and “laminate” may be used interchangeably. Similarly, the terms “chip,” “chiplet,” and “die” may be used interchangeably.

Aspects of the present disclosure are directed to a power/thermal via for 3D chip stacking. In some aspects of the present disclosure, a 3D stacked chip includes a first die having a front-side surface and a backside surface, opposite the front-side surface, the backside surface on a front-side surface of a first redistribution layer (RDL). The 3D stacked chip also includes a second die having a front-side surface on the front-side surface of the first die and a backside surface distal from the first RDL. In various aspects of the present disclosure, the 3D stacked chip includes a via extending from the backside surface of the second die to a back-end-of-line (BEOL) layer of the second die to independently power the first die and the second die.

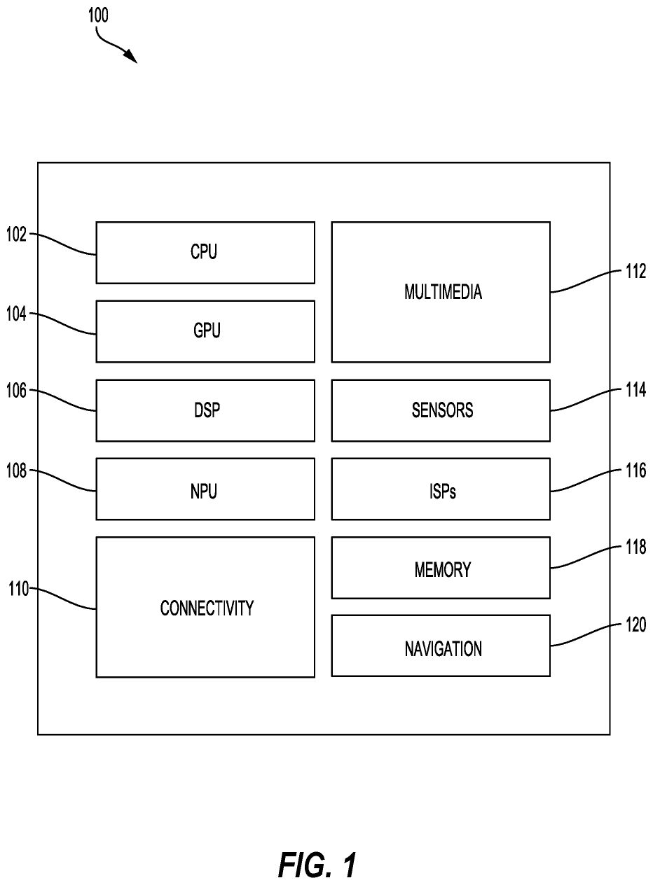

FIG. 1 illustrates an example implementation of a host system-on-a-chip (SOC) 100, which includes a power and/or thermal via for 3D chip stacking, in accordance with certain aspects of the present disclosure. The host SOC 100 includes processing blocks tailored to specific functions, such as a connectivity block 110. The connectivity block 110 may include sixth generation (6G) connectivity, fifth generation (5G) new radio (NR) connectivity, fourth generation long term evolution (4G LTE) connectivity, Wi-Fi connectivity, USB connectivity, Bluetooth® connectivity, Secure Digital (SD) connectivity, and the like.

In this configuration, the host SOC 100 includes various processing units that support multi-threaded operation. For the configuration shown in FIG. 1, the host SOC 100 includes a multi-core central processing unit (CPU) 102, a graphics processor unit (GPU) 104, a digital signal processor (DSP) 106, and a neural processor unit (NPU) 108. The host SOC 100 may also include a sensor processor 114, image signal processors (ISPs) 116, a navigation module 120, which may include a global positioning system (GPS), and a memory 118. The multi-core CPU 102, the GPU 104, the DSP 106, the NPU 108, and the multi-media engine 112 support various functions such as video, audio, graphics, gaming, artificial networks, and the like. Each processor core of the multi-core CPU 102 may be a reduced instruction set computing (RISC) machine, RISC-V, an advanced RISC machine (ARM), a microprocessor, or any reduced instruction set computing (RISC) architecture. The NPU 108 may be based on an ARM instruction set.

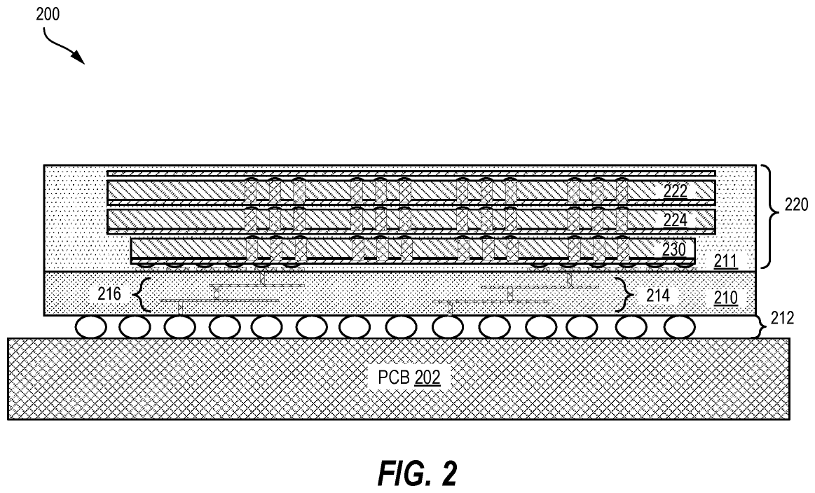

FIG. 2 shows a cross-sectional view of a stacked integrated circuit (IC) package 200 of the host system-on-a-chip (SOC) 100 of FIG. 1. Representatively, the stacked IC package 200 includes a printed circuit board (PCB) 202 connected to a package substrate 210 with interconnects 212. In this configuration, the package substrate 210 includes conductive layers 214 and 216. Above the package substrate 210 is a 3D chip stack 220, including stacked dies 222, 224, and 230, encapsulated by mold compound 211. In one aspect of the present disclosure, the die 230 is the host SOC 100 of FIG. 1.

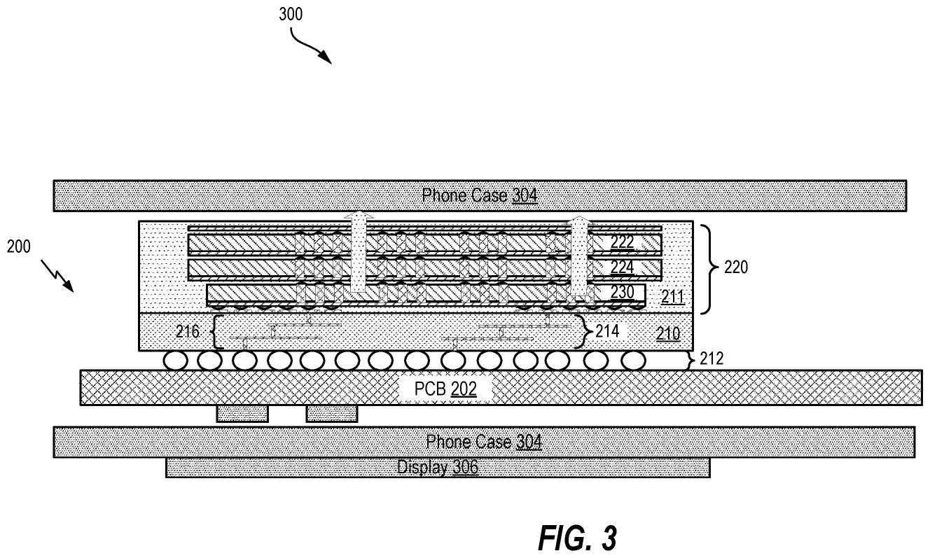

FIG. 3 shows a cross-sectional view illustrating the stacked integrated circuit (IC) package 200 of FIG. 2, incorporated into a wireless device 300, according to one aspect of the present disclosure. As described, the wireless device 300 may include, but is not limited to, a smartphone, tablet, handheld device, or other limited form factor device configured for 5G NR/6G communications.

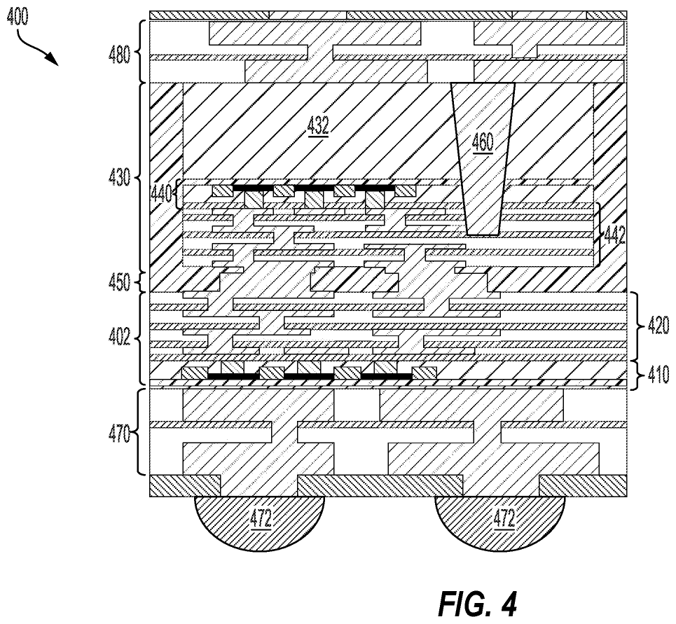

Representatively, the stacked IC package 200 is within a phone case 304, including a display 306. In this configuration, a power/thermal via is integrated in the stacked IC package 200 to support 3D chip stacking, for example, as shown in FIGS. 4 to 7G.

FIG. 4 is a block diagram illustrating cross-sectional views of a 3D stacked chip 400 having a power/thermal via, according to various aspects of the present disclosure. As shown in FIG. 4, the 3D stacked chip 400 includes a first die 402, having an active layer 410 and back-end-of-line (BEOL) layers 420 coupled to active devices of the active layer 410. In this example, a first redistribution layer (RDL) 470 is coupled to a backside of the first die 402. Additionally, the 3D stacked chip 400 includes a second die 430, having an active layer 440 and BEOL layers 442 coupled to the active devices of the active layer 440.

As shown in FIG. 4, the 3D stacked chip 400 includes a power/thermal via 460 (also simply referred to as the via 460 herein) extending from the backside surface of the second die 430 to the BEOL layers 442 of the second die 430 to independently power the first die 402 and the second die 430. As further discussed below, the via 460 can be configured as a power via in some implementations, or as a thermal via in some other implementations. The 3D stacked chip 400 further includes a second RDL 480 having a front-side surface on the backside surface of the second die 430, in which the second RDL 480 is distal from the first RDL 470 and directly couples to the power/thermal via 460. In this example, the second die 430 includes a substrate 432 having the active layer 440 coupled to the BEOL layers 442 of the second die 430 and distal from the backside surface of the first die 402.

In various aspects of the present disclosure, the power via 460 extends from the second RDL 480 through the substrate 432 and the active layer 440 to the BEOL layers 442 of the second die 430. As shown in FIG. 4, the first die 402 and the second die 430 are bonded face-to-face (F2F) using hybrid copper bonding (HCB) pads 450, although other configurations for stacking the first die 402 and the second die 430 are contemplated according to various aspects of the present disclosure. Additionally, the first die 402 and the second die 430 may be implemented using a complementary metal oxide semiconductor (CMOS), in which the substrate 432 is composed of a semiconductor material (e.g., silicon) or a compound semiconductor material (e.g., a III-V compound semiconductor material). Package bumps 472 couple the 3D stacked chip 400 to a package substrate, printed circuit board (PCB), or another like substrate/package.

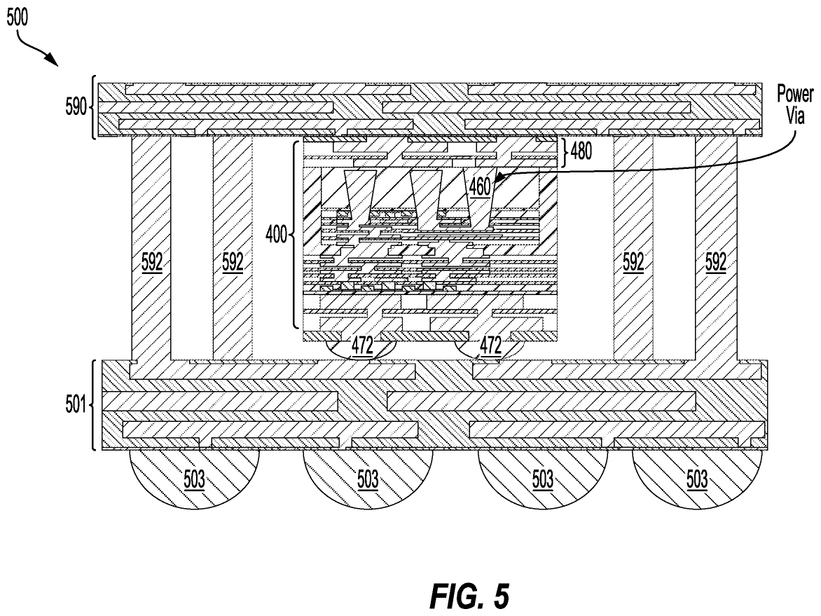

FIG. 5 is a block diagram illustrating the 3D stacked chip 400 of FIG. 4 in a package-on-package (POP) 500 configuration, according to various aspects of the present disclosure. As shown in FIG. 5, the 3D stacked chip 400 of FIG. 4 is described using the same reference numbers in the PoP 500. In this example, the POP 500 is supported by a printed circuit board (PCB) 501, having package balls 503 and coupled to the package bumps 472 of the 3D stacked chip 400. Additionally, the PoP 500 includes a package substrate 590 coupled to a surface of the second RDL 480, and the package substrate 590 is coupled to the PCB 501 through conductive pillars 592. According to various aspects of the present disclosure, the power via 460 supports improved power density by supplying power to both a front-side and a backside of the 3D stacked chip 400.

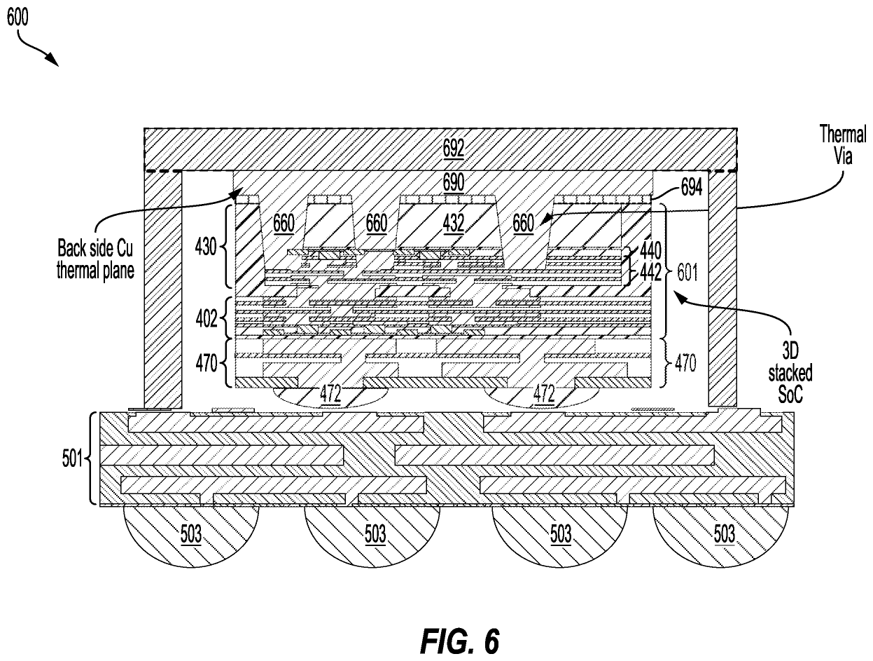

FIG. 6 is a block diagram illustrating the 3D stacked system-on-a-chip (SOC) 601 in a lidded package configuration 600, according to various aspects of the present disclosure. The 3D stacked SOC 601 is described using similar reference numbers to the 3D stacked chip 400 of FIG. 4 in the lidded package configuration 600 of FIG. 6. As shown in FIG. 6, the 3D stacked SOC 601 is composed of the first die 402 and the second die 430 of the 3D stacked chip 400 of FIG. 4. In various aspects of the present disclosure, thermal vias 660 extend from the backside of the second die 430, through the substrate 432 and the active layer 440 to the BEOL layers 442 of the second die 430. Additionally, a backside thermal plate 690 is coupled to the thermal vias 660 and the substrate 432 of the second die 430 through a thermal interface layer 694.

In this example, the lidded package configuration 600 is supported by the PCB 501, having the package balls 503 and coupled to the package bumps 472 of the first RDL 470. Additionally, the lidded package configuration 600 includes a thermal lead 692 coupled to a surface of the backside thermal plate 690. In this example, the thermal lead 692 is coupled to the PCB 501. According to various aspects of the present disclosure, a via structure of the thermal vias 660 provides substantial thermal dissipation to a top side of the 3D stacked SOC 601 as well as overall thermal management/design of the lidded package configuration 600. Additionally, placement of the thermal vias 660 on the top side of the 3D stacked SOC 601 supports a total Z-height specification for complying with thermal specifications in reduced 3D stacked chips.

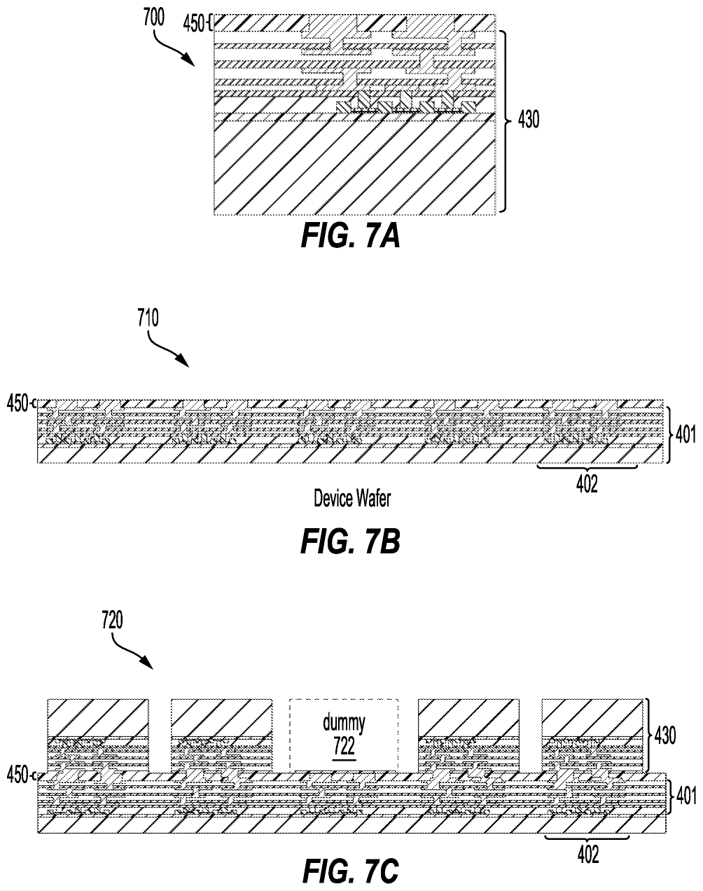

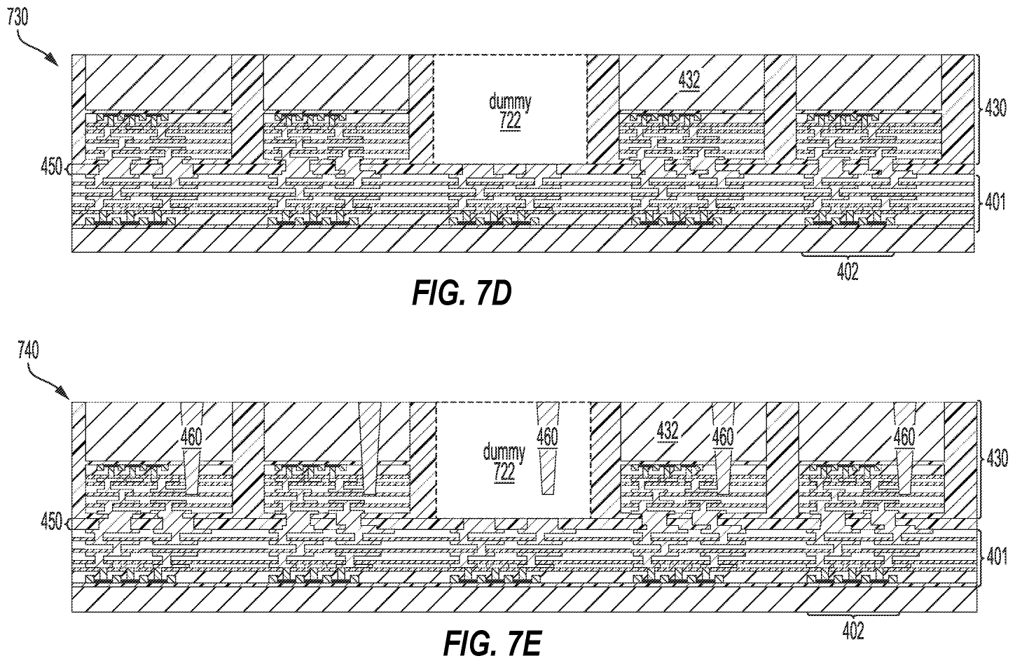

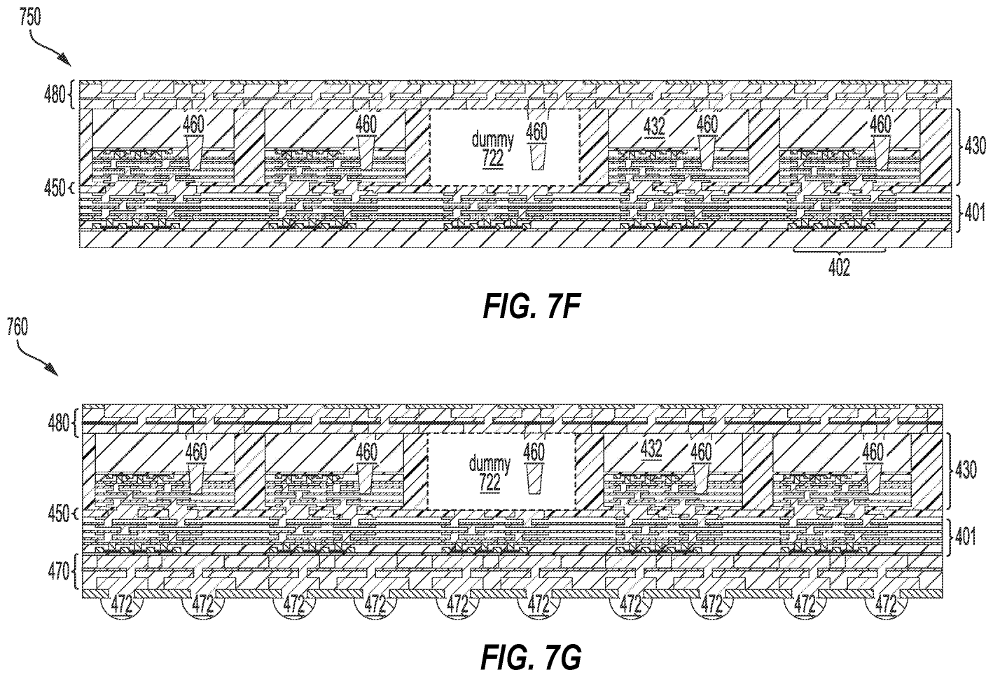

A process of fabricating a 3D stacked chip is shown in FIGS. 7A-7G. FIGS. 7A-7G are cross-sectional diagrams illustrating a process for fabricating the 3D stacked chip 400 of FIG. 4, having the power via 460, according to various aspects of the present disclosure.

FIG. 7A illustrates a first step 700 for fabricating the 3D stacked chip 400 of FIG. 4, having the power via 460. In various aspects of the present disclosure, a smart chip device front-end-of-line (FEOL) process i forms the second die 430. This FEOL process is followed by a middle-of-line (MOL)/back-end-of-line (BEOL) process to complete formation of the second die 430. Additionally, the HCB pads 450 are formed on the second die 430.

FIG. 7B illustrates a second step 710 for fabricating the 3D stacked chip 400 of FIG. 4, having the power via 460, according to various aspects of the present disclosure. The second step 710 illustrates a device wafer composed of the first die 402, including the HCB pads 450, which is referred to as a first die wafer 401.

FIG. 7C illustrates a third step 720 for fabricating the 3D stacked chip 400 of FIG. 4, having the power via 460, according to various aspects of the present disclosure. The third step 720 illustrates a through substrate via (TSV)-less face-to-face (F2F) 3D stacking of the second die 430 on a first die wafer 401 composed of the first die 402, as shown in FIG. 7B. According to various aspects of the present disclosure, the second die 430 is bonded to the first die wafer 401 of the first die 402 using the HCB pads 450, which may be composed of a copper (Cu) tungsten (W) (CuW) material, although other like conductive materials are contemplated. Additionally, a dummy die 722 is also bonded to the first die wafer 401 of the first die 402.

FIG. 7D illustrates a fourth step 730 for fabricating the 3D stacked chip 400 of FIG. 4, having the power via 460, according to various aspects of the present disclosure. The fourth step 730 illustrates an oxide gap fill between the second die 430 and polishing of a backside surface of the second die 430.

FIG. 7E illustrates a fifth step 740 for fabricating the 3D stacked chip 400 of FIG. 4, having the via 460, according to various aspects of the present disclosure. The fifth step 740 illustrates formation of the via 460, extending from the backside of the second die 430, through the substrate 432 and the active layer 440, and stopping in the BEOL layers 442 (see FIG. 4). Formation of the via 460 may include a lithographic step to define the via 460 followed by an etch process to form a via opening that exposes one of the BEOL layers 442. A metallization process (e.g., barrier/liner deposition followed by a metal plating step to fill the via opening. For example, the metal plating step my involve a copper plating step or other like metal plating step (e.g., tungsten plating). Subsequently, a chemical mechanical polishing (CMP) process is performed to complete formation of the via 460.

FIG. 7F illustrates a sixth step 750 for fabricating the 3D stacked chip 400 of FIG. 4, having the power via 460, according to various aspects of the present disclosure. The sixth step 750 further illustrates initial formation of the second RDL 480 on the backside surface of the second die 430 utilizing a backside RDL process.

FIG. 7G illustrates a seventh step 760 for fabricating the 3D stacked chip 400 of FIG. 4, having the power via 460, according to various aspects of the present disclosure. The seventh step 760 further illustrates formation of the first RDL 470 on the backside surface of the first die wafer 401 of the first die 402 utilizing a backside RDL process. This process involves thinning of the backside of the first die wafer 401 and stopping on an embedded device etch stop layer, for example, in a substrate of the first die wafer 401. This is followed by forming the package bumps 472 on a backside of the first RDL 470 and singulating the first die wafer 401 from the 3D stacked chip 400 of FIG. 4.

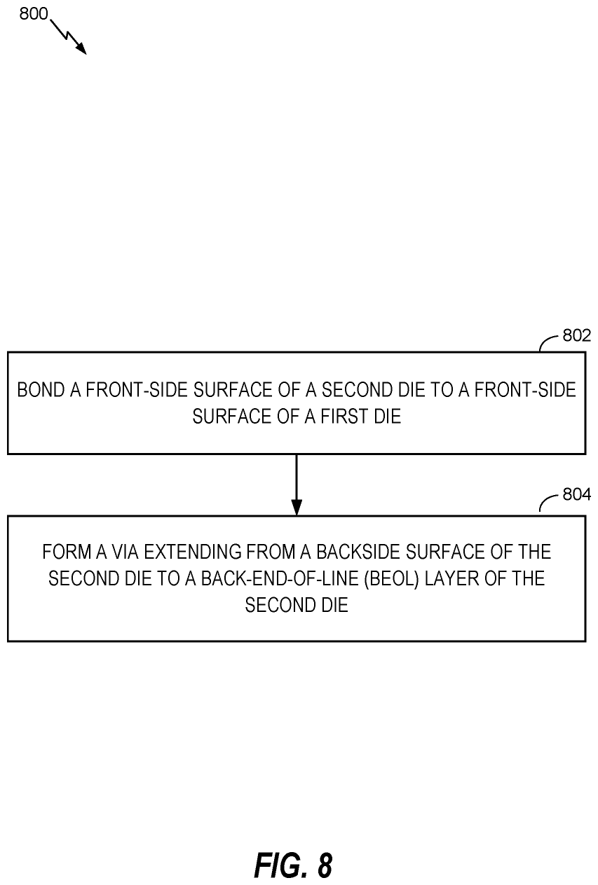

FIG. 8 is a process flow diagram illustrating a method 800 for fabricating a 3D stacked chip, according to various aspects of the present disclosure. The method 800 begins at block 802, in which a front-side surface of a second die is bonded to a front-side surface of a first die. For example, as shown in FIG. 4, the first die 402 and the second die 430 are bonded face-to-face (F2F) using hybrid copper bonding (HCB) pads 450, although other configurations for stacking the first die 402 and the second die 430 are contemplated according to various aspects of the present disclosure. Additionally, the first die 402 and the second die 430 may be implemented using a complementary metal oxide semiconductor (CMOS), in which the substrate 432 is composed of a semiconductor material (e.g., silicon) or a compound semiconductor material (e.g., a III-V compound semiconductor material).

At block 804, a via is formed extending from a backside surface of the second die to a back-end-of-line (BEOL) layer of the second die. For example, as shown in FIG. 4, the 3D stacked chip 400 includes a power/thermal via 460 (also simply referred to as the via 460 herein) extending from the backside surface of the second die 430 to the BEOL layers 442 of the second die 430 to independently power the first die 402 and the second die 430. As further discussed below, the via 460 can be configured as a power via in some implementations, or as a thermal via in some other implementations.

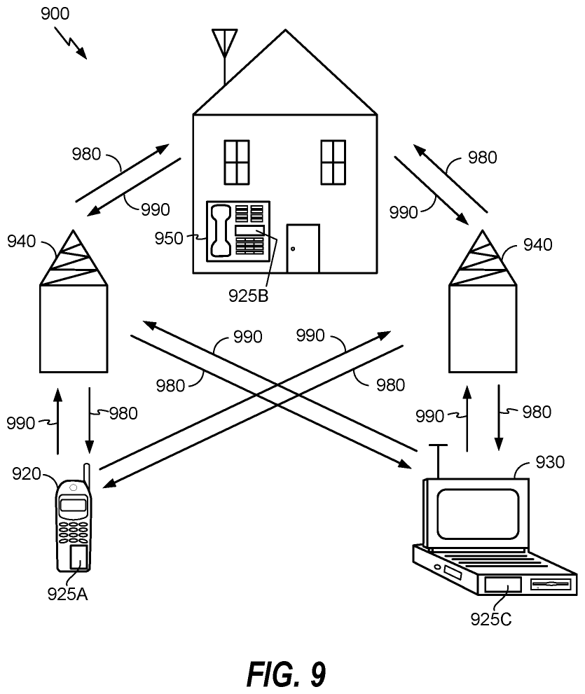

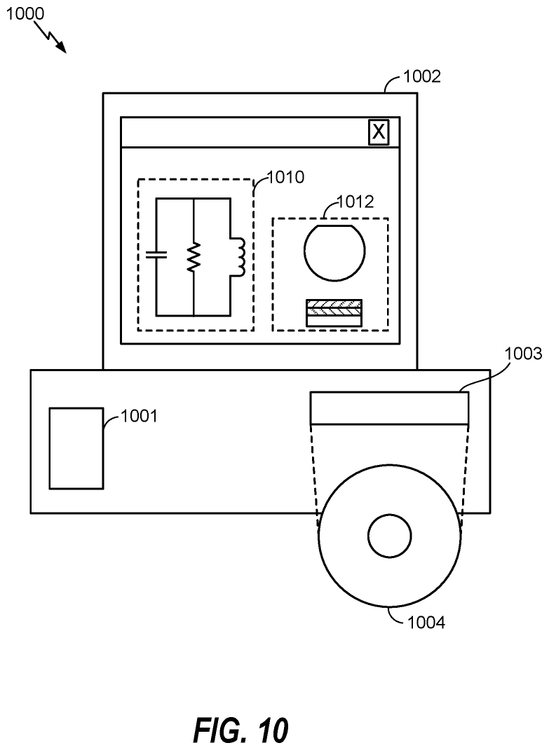

FIG. 9 is a block diagram showing an exemplary wireless communications system 900, in which an aspect of the present disclosure may be advantageously employed. For purposes of illustration, FIG. 9 shows three remote units 920, 930, and 950, and two base stations 940. It will be recognized that wireless communications systems may have many more remote units and base stations. Remote units 920, 930, and 950 include integrated circuit (IC) devices 925A, 925B, and 925C that include the disclosed 3D stacked chip. It will be recognized that other devices may also include the disclosed 3D stacked chip, such as the base stations, switching devices, and network equipment. FIG. 9 shows forward link signals 980 from the base stations 940 to the remote units 920, 930, and 950, and reverse link signals 990 from the remote units 920, 930, and 950 to the base stations 940.

In FIG. 9, remote unit 920 is shown as a mobile telephone, remote unit 930 is shown as a portable computer, and remote unit 950 is shown as a fixed location remote unit in a wireless local loop system. For example, the remote units may be a mobile phone, a hand-held personal communication systems (PCS) unit, a portable data unit, such as a personal data assistant, a GPS enabled device, a navigation device, a set top box, a music player, a video player, an entertainment unit, a fixed location data unit, such as meter reading equipment, or other device that stores or retrieves data or computer instructions, or combinations thereof. Although FIG. 9 illustrates remote units according to the aspects of the present disclosure, the disclosure is not limited to these exemplary illustrated units. Aspects of the present disclosure may be suitably employed in many devices, which include the disclosed 3D stacked chip.

FIG. 10 is a block diagram illustrating a design workstation 1000 used for circuit, layout, and logic design of a semiconductor component, such as the 3D stacked chip disclosed above. The design workstation 1000 includes a hard disk 1001 containing operating system software, support files, and design software such as Cadence or OrCAD. The design workstation 1000 also includes a display 1002 to facilitate design of a circuit 1010 or a semiconductor component 1012, such as the 3D stacked chip. A storage medium 1004 is provided for tangibly storing the design of the circuit 1010 or the semiconductor component 1012 (e.g., the 3D stacked chip). The design of the circuit 1010 or the semiconductor component 1012 may be stored on the storage medium 1004 in a file format such as GDSII or GERBER. The storage medium 1004 may be a CD-ROM, DVD, hard disk, flash memory, or other appropriate device. Furthermore, the design workstation 1000 includes a drive apparatus 1003 for accepting input from or writing output to the storage medium 1004.

Data recorded on the storage medium 1004 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1004 facilitates the design of the circuit 1010 or the semiconductor component 1012 by decreasing the number of processes for designing semiconductor wafers.

Implementation examples are described in the following numbered clauses:
1. A three-dimensional (3D) stacked chip, comprising:
a first die having a front-side surface and a backside surface, opposite the front-side surface, the backside surface on a front-side surface of a first redistribution layer (RDL);
a second die having a front-side surface on the front-side surface of the first die and a backside surface being distal from the first RDL; and
a via extending from the backside surface of the second die to a back-end-of-line (BEOL) layer of the second die.
2. The 3D stacked chip of clause 1, further comprising a second RDL having a front-side surface on the backside surface of the second die, the second RDL being distal from the first RDL, in which the via is directly coupled to the second RDL.
3. The 3D stacked chip of any of clauses 1 or 2, in which the second die comprises a substrate having an active layer coupled to the BEOL layer of the second die and distal from the backside surface of the second die, in which the via extends through the substrate and the active layer to the BEOL layer of the second die.
4. The 3D stacked chip of clause 3, further comprising a thermal plate on the backside surface of the second die, in which the via is a thermal via that extends from the thermal plate and through the substrate and the active layer to the BEOL layer of the second die.
5. The 3D stacked chip of clause 4, further comprising a thermal lead coupled to the thermal plate.
6. The 3D stacked chip of clause 3, further comprising a second RDL on the backside surface of the second die, in which the via is a power via that extends from the second RDL through the substrate and the active layer to the BEOL layer of the second die.
7. The 3D stacked chip of any of clauses 1-5, in which the backside surface of the second die comprises a thermal interface layer.
8. The 3D stacked chip of any of clauses 1-7, further comprising a printed circuit board coupled to the first die through package bumps.
9. The 3D stacked chip of any of clauses 1-8, in which the front-side surface of the first die is directly bonded to the front-side surface of the second die to couple the BEOL layer of the second die to a BEOL layer of the first die.
10. The 3D stacked chip of any of clauses 1-9, further comprising a package substrate coupled to a backside surface of a second RDL on the backside surface of the second die.
11. A method for fabricating a three-dimensional (3D) stacked chip, the method comprising:
bonding a front-side surface of a second die to a front-side surface of a first die; and
forming a via extending from a backside surface of the second die to a back-end-of-line (BEOL) layer of the second die.
12. The method of clause 11, further comprising:
fabricating the first die having the front-side surface and a backside surface, opposite the front-side surface, the backside surface on a front-side surface of a first redistribution layer (RDL); and
fabricating the second die having the front-side surface on the front-side surface of the first die and the backside surface being distal from the first RDL.
13. The method of clause 12, further comprising forming a second RDL having a front-side surface on the backside surface of the second die, the second RDL being distal from the first RDL, in which the via is directly coupled to the second RDL.
14. The method of any of clauses 11-14, in which the second die comprises a substrate having an active layer coupled to the BEOL layer of the second die and distal from the backside surface of the second die, in which the via extends through the substrate and the active layer to the BEOL layer of the second die.
15. The method of clause 14, further comprising:
forming a thermal plate on the backside surface of the second die, in which the via is a thermal via that extends from the thermal plate and through the substrate and the active layer to the BEOL layer of the second die; and
forming a thermal lead coupled to the thermal plate.
16. The method of clause 14, further comprising forming a second RDL on the backside surface of the second die, in which the via is a power via that extends from the second RDL through the substrate and the active layer to the BEOL layer of the second die.
17. The method of any of clauses 11-15, in which the backside surface of the second die comprises a thermal interface layer.
18. The method of any of clauses 11-17, further comprising a printed circuit board coupled to the first die through package bumps.
19. The method of any of clauses 11-18, in which the front-side surface of the first die is directly bonded to the front-side surface of the second die to couple the BEOL layer of the second die to a BEOL layer of the first die.
20. The method of any of clauses 11-19, further comprising a package substrate coupled to a backside surface of a second RDL on the backside surface of the second die.

For a firmware and/or software implementation, the methodologies may be implemented with modules (e.g., procedures, functions, and so on) that perform the functions described. A machine-readable medium tangibly embodying instructions may be used in implementing the methodologies described. For example, software codes may be stored in a memory and executed by a processor unit. Memory may be implemented within the processor unit or external to the processor unit. As used, the term “memory” refers to types of long term, short term, volatile, nonvolatile, or other memory and is not limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include random access memory (RAM), read-only memory (ROM), electrically erasable read-only memory (EEPROM), compact disc read-only memory (CD-ROM) or other optical disk storage, magnetic disk storage or other magnetic storage devices, or other medium that can be used to store desired program code in the form of instructions or data structures and that can be accessed by a computer. Disk and disc, as used, include compact disc (CD), laser disc, optical disc, digital versatile disc (DVD), floppy disk, and Blu-Ray® disc, where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communications apparatus. For example, a communications apparatus may include a transceiver having signals indicative of instructions and data. The instructions and data are configured to cause one or more processors to implement the functions outlined in the claims.

Although the present disclosure and its advantages have been described in detail, various changes, substitutions, and alterations can be made without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present disclosure is not intended to be limited to the configurations of the process, machine, manufacture, composition of matter, means, methods, and steps described in the specification. As one of ordinary skill in the art will readily appreciate from the present disclosure, processes, machines, manufacture, compositions of matter, means, methods, or steps, presently existing or later to be developed that perform the same function or achieve the same result as the corresponding configurations described may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the present disclosure may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the application and design constraints imposed on the overall system. Skilled artisans may implement the described functionality in varying ways for each application, but such implementation decisions should not be interpreted as causing a departure from the scope of the present disclosure.

The various illustrative logical blocks, modules, and circuits described in connection with the disclosure may be implemented or performed with a general-purpose processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described. A general-purpose processor may be a microprocessor, but, in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the present disclosure may be embodied directly in hardware, in a software module executed by a processor, or in a combination of the two. A software module may reside in RAM, flash memory, ROM, erasable programmable read-only memory (EPROM), EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The previous description of the present disclosure is provided to enable any person skilled in the art to make or use the present disclosure. Various modifications to the disclosure will be readily apparent to those skilled in the art, and the generic principles defined may be applied to other variations without departing from the spirit or scope of the disclosure. Thus, the present disclosure is not intended to be limited to the examples and designs described but is to be accorded the widest scope consistent with the principles and novel features disclosed.

What is claimed is:

1. A three-dimensional (3D) stacked chip, comprising:
a first die having a front-side surface and a backside surface, opposite the front-side surface, the backside surface on a front-side surface of a first redistribution layer (RDL);
a second die having a front-side surface on the front-side surface of the first die and a backside surface being distal from the first RDL; and
a via extending from the backside surface of the second die to a back-end-of-line (BEOL) layer of the second die.

2. The 3D stacked chip of claim 1, further comprising a second RDL having a front-side surface on the backside surface of the second die, the second RDL being distal from the first RDL, in which the via is directly coupled to the second RDL.

3. The 3D stacked chip of claim 1, in which the second die comprises a substrate having an active layer coupled to the BEOL layer of the second die and distal from the backside surface of the second die, in which the via extends through the substrate and the active layer to the BEOL layer of the second die.

4. The 3D stacked chip of claim 3, further comprising a thermal plate on the backside surface of the second die, in which the via is a thermal via that extends from the thermal plate and through the substrate and the active layer to the BEOL layer of the second die.

5. The 3D stacked chip of claim 4, further comprising a thermal lead coupled to the thermal plate.

6. The 3D stacked chip of claim 3, further comprising a second RDL on the backside surface of the second die, in which the via is a power via that extends from the second RDL through the substrate and the active layer to the BEOL layer of the second die.

7. The 3D stacked chip of claim 1, in which the backside surface of the second die comprises a thermal interface layer.

8. The 3D stacked chip of claim 1, further comprising a printed circuit board coupled to the first die through package bumps.

9. The 3D stacked chip of claim 1, in which the front-side surface of the first die is directly bonded to the front-side surface of the second die to couple the BEOL layer of the second die to a BEOL layer of the first die.

10. The 3D stacked chip of claim 1, further comprising a package substrate coupled to a backside surface of a second RDL on the backside surface of the second die.

11. A method for fabricating a three-dimensional (3D) stacked chip, the method comprising:
bonding a front-side surface of a second die to a front-side surface of a first die; and
forming a via extending from a backside surface of the second die to a back-end-of-line (BEOL) layer of the second die.

12. The method of claim 11, further comprising:
fabricating the first die having the front-side surface and a backside surface, opposite the front-side surface, the backside surface on a front-side surface of a first redistribution layer (RDL); and
fabricating the second die having the front-side surface on the front-side surface of the first die and the backside surface being distal from the first RDL.

13. The method of claim 12, further comprising forming a second RDL having a front-side surface on the backside surface of the second die, the second RDL being distal from the first RDL, in which the via is directly coupled to the second RDL.

14. The method of claim 11, in which the second die comprises a substrate having an active layer coupled to the BEOL layer of the second die and distal from the backside surface of the second die, in which the via extends through the substrate and the active layer to the BEOL layer of the second die.

15. The method of claim 14, further comprising:
forming a thermal plate on the backside surface of the second die, in which the via is a thermal via that extends from the thermal plate and through the substrate and the active layer to the BEOL layer of the second die; and
forming a thermal lead coupled to the thermal plate.

16. The method of claim 14, further comprising forming a second RDL on the backside surface of the second die, in which the via is a power via that extends from the second RDL through the substrate and the active layer to the BEOL layer of the second die.

17. The method of claim 11, in which the backside surface of the second die comprises a thermal interface layer.

18. The method of claim 11, further comprising a printed circuit board coupled to the first die through package bumps.

19. The method of claim 11, in which the front-side surface of the first die is directly bonded to the front-side surface of the second die to couple the BEOL layer of the second die to a BEOL layer of the first die.

20. The method of claim 11, further comprising a package substrate coupled to a backside surface of a second RDL on the backside surface of the second die.
